(19) United States
(12) Patent Application Publication
(10) Pub. No.: US 2006/0043372 A1
(43) Pub. Date: Mar. 2, 2006

(54) Light emitting devices and arrays with reduced electrode resistance

(76) Inventors: Cindy X. Qiu, Brossard (CA); Chunong Qiu, Brossard (CA); Yi-Chi Shih, Palos Verdes Estates, CA (US)

Correspondence Address: Cindy X. Qiu, 6215 Bienville St., Brossard, QC, J4Z 1W6, CA

(21) Appl. No.: 10/928,994

(22) Filed: Aug. 30, 2004

(51) Int. Cl. H01L 29/04; H01L 31/20

(52) U.S. Cl. 257/72; 257/59

(57) ABSTRACT

For light emitting devices used in conventional information displays, the dimensions of each light emitting device are small and the effect of series resistance of electrodes is not too severe in affecting the performance of the displays. When the dimensions or areas of the devices increase for large area display applications, the effect of series resistance becomes significant. This invention provides a light emitting device and array having a reduced effective series resistance for the optically transparent and electrically conducting oxide electrodes.

### BACKGROUND OF THE INVENTION

1. Field of the Invention

This invention relates to organic light emitting devices, organic light emitting arrays, inorganic light emitting devices and inorganic light emitting arrays. More specifically, this invention relates to structures and methods of light emitting devices and arrays to reduce the series resistance associated with such devices and arrays.

2. Description of the Prior Art

There are two main technologies for the flat panel electronic displays: one is based on liquid crystal devices and the other is based on light emitting devices. Liquid crystal devices in electronic displays usually consist of a thin sheet of electrically insulated liquid crystal layer sandwiched between two electrically conducting and optically transparent electrodes often deposited on separate transparent substrates such as glass plates. A first polarizer is disposed on one substrate and a second polarizer is disposed on the other substrate. A portion of light incident on the first polarizer will be allowed to transmit and reach the liquid crystal layer. When a voltage is applied between the two electrically conducting electrodes, a change is brought about in the polarization of the light passing through the first polarizer. Depending on the orientation of the second polarizer with respect to the first polarizer, the light passing through the liquid crystal layer may be blocked by the second polarizer or be allowed to transmit through the second polarizer. It is thus clear that liquid crystal devices in most electronic displays do not emit light and are acting as a light valve. Additionally, due to the fact that polarization of the liquid crystals is affected by the application of an electric field, the liquid crystal materials may be designed and fabricated in such a way that they have a very large electrical resistivity. Hence, between the two electrically conducting electrodes, a liquid crystal device is equivalent to a simple capacitor. Whereas the electrically conducting and optically transparent electrodes are often metal oxides such as indium tin oxide (ITO) or zinc oxide (ZnO). Although these metal oxides are conducting, their electrical resistivity values are much larger than conventional metals such as aluminum (Al) or gold (Au). The resistivity of the best conducting oxides is about 2 to 3 orders of magnitude greater than that of these metals. Hence, there is a series resistance associated with the two electrically conducting electrodes which can lead to a loss of electrical power due to a joule heating effect.

In addition, when a current is flowing through these electrodes, an unavoidable voltage-drop along the electrodes will lead to a decrease in the voltage along the path of the current. It is noted that the voltage at a given location of the electrodes determines the electric field and switching effects of the liquid crystal layer. During the switching of such liquid crystal devices, the capacitor of the device goes through charging and discharging processes and the amount of charges needs to be supplied or removed is proportional to the capacitance of the capacitor. The capacitance of a liquid crystal device is proportional to the effective area and dielectric constant of the device and is inversely proportional to the distance between the two electrodes (this distance is often called cell gap). For conventional liquid crystal devices with a cell gap of a few micrometers, the charging and discharging current during switching at a given switching voltage is small. Hence, the unwanted joule heating or the voltage decrease due to the flow of this current through the series resistor associated with the two electrodes is fairly small.

On the other hand, the situation for light emitting devices or light emitting arrays is quite different from that for the liquid crystal devices. This is because a relatively large current is required to flow through a light emitting device when it is turned on and when it stays in the ON state. To illustrate this effect, refer to FIG. 1 which shows a portion of an electronic display array (10) based on light emitting devices (11) with a bottom electrode (11′, FIG. 2) situated underneath. The light emitting devices (11) are arranged in a two dimensional configuration on a bottom substrate (12). A thin film transistor (TFT, 13) is connected to each light emitting device (11) to facilitate the switching. The gates of all TFTs (13) in one row are connected to a gate line or row electrical line (14) in order to select and turned on specific TFTs (13). The electrical signals to be supplied to the light emitting devices (11) in the selected row are sent to the source of these TFTs (13) through the column electrical lines or data lines (15). When a TFT (13) is selected with a gate voltage applied to the row electrical line or gate line (14), electrical signals can flow from the column electrical line or data line (15) through the source, channel and drain to a pixel electrode or bottom electrode (11′). There are applications where the switching of the light emitting devices is achieved without the TFTs (13) or switching means of the light emitting element being connected. A top electrode (16) deposited on a top substrate (17) is positioned in the space (18), between the bottom substrate (12) and the top substrate (17). In order to allow the emitting light to escape, at least one of the two electrodes (11′ and 16) must be optically transparent.

Unlike the liquid crystal devices, optical polarizers are not required because the thin sheet of the semiconductor layer will emit light when a voltage or current is applied.

As stated before, at least one of the electrically conducting electrodes (11′ and 16) must be optically transparent. Refer to FIG. 2 for a schematic top view of a light emitting device (11) in an array (10). To simplify the description, the TFTs (13) shown in FIG. 1 are not included in FIG. 2, so that a plurality of the light emitting device (11) will form a passive matrix array. The light emitting device (11) is fabricated with an electrically conducting and optically transparent bottom electrode (11′) deposited on a substrate (12). The bottom electrode (11′) is connected electrically to the data line (15) whereas the row line (14) is connected to a top electrode (16). The materials for the bottom electrode (11′) are common metal oxides such as indium tin oxide (ITO) or zinc oxide (ZnO). However, their electrical resistivity values are larger than conventional metal such as aluminum (Al) or gold (Au) (the resistivity of the best conducting oxides is about 2 to 3 orders of magnitude greater than that of these metals). Due to the finite resistivity, a potential drop along the path of the current (19) is present in these electrodes (11′). Hence, the actual voltage at a specific location (A) will be different from another location (B), leading to a difference in the electric fields between the two locations (A and B). It should be noted that the intensity of emitted light from a given location is a direct function of the electric field. Hence, the emitted light intensity from the location (A) which is closer to the data line (15, connect to the source of current) will be stronger than that from location (B) which is further away from the data line (15). Hence, the intensity of emitted light may not be uniform when the required current density is large or when the dimensions of the light emitting device (11) are large.

The non-uniformity in light emission is particularly severe for the semiconductor layers requiring a low emission voltage, such as the light emitting devices based on organic semiconductor layers. In such devices, in order to achieve high enough light intensity, the current density is often large and therefore the uniformity problem due to the potential drop along the path of the metal oxide electrodes has caused difficulty in achieving large area light emitting devices.

Based on the above comments, it is highly desirable to have a structure or s method which can reduce the potential drop along the path of electrically conducting and optically transparent electrodes in order to achieve light emitting devices or displays with uniform light intensities.

### SUMMARY OF THE INVENTION

One objective of the present invention is to provide a light emitting device structure having a plurality of metal strips deposited between a transparent-conducting layer and a light emitting layer to reduce the series resistance of the transparent-conducting layer. Another objective of this invention is to provide a light emitting device structure having a plurality of metal strips deposited between a substrate and a transparent-conducting layer to reduce the series resistance of the transparent-conducting layer. Yet another objective of the present invention is to provide methods for the fabrication of the light emitting devices having reduced series resistance.

### BRIEF DESCRIPTION OF THE DRAWINGS

FIG. 1 shows a schematic diagram of a conventional light emitting array (10).

FIG. 2 shows a schematic top view of a conventional light emitting device (11).

FIG. 3 shows a schematic top view of a light emitting device (30) with a plurality of bottom grid electrodes for the reduction of electrode resistance.

FIG. 4 shows a schematic cross-sectional view of the light emitting device (30) taken along C-C′ in FIG. 3, where the first grid electrode is deposited on the first electrode.

FIG. 5 shows a schematic cross-sectional view of the light emitting device (30) taken along C-C′ in FIG. 3, where the first grid electrode is deposited under the first electrode.

FIG. 6 shows a schematic cross-sectional view of the light emitting device (30) taken along C-C′ in FIG. 3, where a second grid electrode is added (the first grid electrode is deposited on the first electrode and the second grid electrode is deposited under the second electrode).

FIG. 7 shows a schematic cross-sectional view of the light emitting device (30) taken along D-D′ in FIG. 3, showing a emitting light (51).

FIG. 8 shows a schematic cross-sectional view of a light emitting device (30′) with a hole-transport layer and an electron-transport layer added.

FIG. 9 shows a schematic top view of a light emitting device (70) with a plurality of bottom grid electrodes for the reduction of series resistance and a thin film transistor (78).

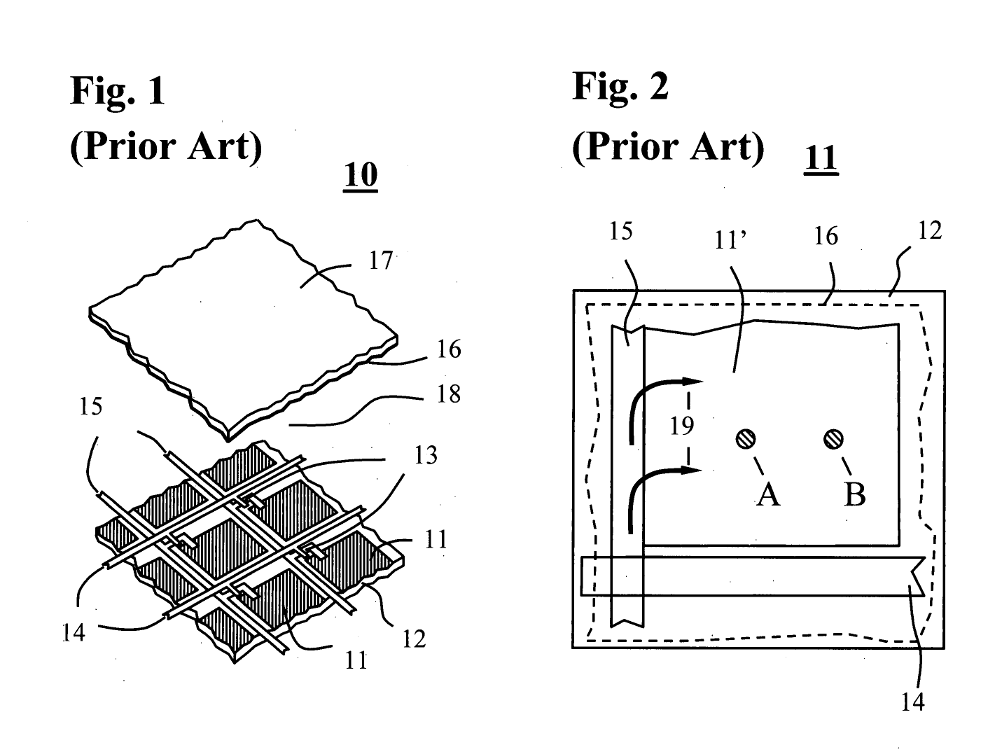

### DETAILED DESCRIPTION OF THE PREFERRED EMBODIMENTS

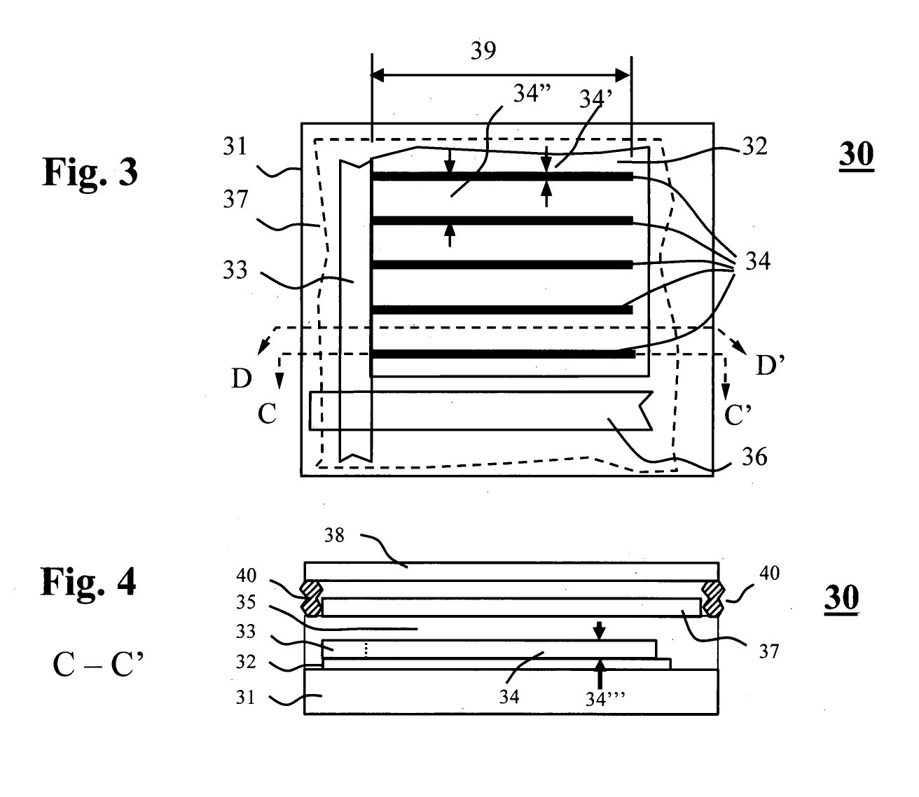

Refer now to FIG. 3 and FIG. 4, where there is shown a top view (FIG. 3) and a cross-sectional view (FIG. 4, taken along C-C′) of a light emitting device (30) in an array that is composed of a plurality of the same devices. This light emitting device (30) consists of a first substrate (31), a first electrode (32), a column line (33), a first grid electrode (34), a light emitting layer (35, in FIG. 4), a row line (36), a second electrode (37) and a second substrate (38). The first substrate (31) is selected preferably from a group of transparent materials such as glass sheets and plastic films. The plastic films include: polyethylene terephthalate (PET) sheets, polyethylene naphthalate (PEN) sheets, polycarbonate (PC), polyethersulfone (PES) polyimide (PI) etc., as long as they are smooth and with a glass transition temperature or softening temperature high enough to withstand the processing conditions (about 90° C.). For simplicity, all substrates fabricated using polymeric materials or organic materials are called plastic films or plastics substrates in this invention. However, the first substrate (31) may also be selected to be none-transparent. The first electrode (32) is preferably a strip of ITO or ZnO, which is optically transparent and relatively electrically conducting (resistivity about 10⁻³-10⁻⁴ ohm-cm) deposited by vacuum deposition or by chemical vapor deposition to a thickness of about 100 to 200 nm and patterned to the predetermined dimensions. After the deposition and patterning of the first electrode (32), a first grid electrode (34) is deposited and patterned to have a grid width (34′) and a grid spacing (34″) between two adjacent grids of the first grid electrode (34). The materials of the first grid electrode (34) are selected from a group of materials with very low electrical resistivity (about 10⁻⁶ ohm-cm) such as: Al, Au, Cu, Ti, Cr and their combinations. Alternately, a multilayer structure may be selected for the first grid electrode (34) in order to improve adhesion of said first grid electrode (34) to said first electrode (32). Therefore, it becomes clear that materials for the first grid electrode (34) may not be required to be transparent and the grid width (34′) of the first grid electrode (34) will be selected to be small as compared to the grid spacing (34″) so that the presence of the first grid electrode (34) of length (39, FIG. 3) does not block substantial amount of light emitted by the light emitting layer (35).

The effect of reduction of the effective series resistance of the first electrode (32) is determined by the selection of the grid width (34′), grid spacing (34″) and the thickness (34′″, in FIG. 4) of the first grid electrode (34). For instance, for a first electrode (32) having a resistivity of 10⁻³ ohm-cm and a thickness of 0.1 μm combined with a first grid electrode (34) with a grid width (34′) of 10 μm, a spacing (34″) of 100 μm, a grid thickness (34′″) of 1 μm and a resistivity of 10⁻⁶ ohm-cm, the effective series resistance of the first electrode (32) with the first grid electrode (34), is about 10⁻³ times of the original value when only the first electrode (32) is employed in the light emitting device (30). It should be noted that the ratio of the grid width (34′) to the grid spacing (34″) defines the amount of emitted light to be block by the first grid electrode (34) and it is preferably to keep the ratio to be as small as possible. In the above example, the percentage of emitted light to be allowed to transmit is 90%. In another example, for a first electrode (32) having a resistivity of 10⁻³ ohm-cm and a thickness of 0.1 μm and a first grid electrode (34) with a grid width (34′) of 1 μm, a spacing (34″) 100 μm, a thickness (34′″) of 1 μm and a resistivity of 10⁻⁶ ohm-cm, the effective series resistance of the first electrode (32) with the first grid electrode (34) is about 10⁻² times of the original value when only the first electrode (32) is employed in the light emitting device (30). The percentage of emitted light to be allowed to transmit is 99% in this case.

The materials of the light emitting layer (35) are selected from a group comprising: inorganic materials such as ZnSe, ZnS, ZnO and their mixtures and small molecule organic materials such as: pentacence, NPB, AlQ3, CuPc, TPD, Irppy and large molecule organic materials such as: MEH-PPV MEH-PPV (Poly[2-methoxy-5-(2′-ethyl-hexyloxy)-1,4-phenylene vinylene]), poly[3-hexylthiophene-2.5diy](P3HT), poly[3-octylthiophene](P3OT), poly[(4-butylphenyl)-diphenyl-amine-4,4-yl] (poly-TPD), and poly[3,3″-didodecyl-2,2′:5′,2″-terthiophene] (PDDTT). Both inorganic materials and the small molecule organic materials are deposited by vacuum deposition or chemical deposition methods whereas the large molecule organic materials are deposited preferably by solution casting or spinning. Typical thickness of the light emitting layer (35) is from 100 nm to 200 nm which is controlled by the deposition conditions.

When organic semiconductors such as Alq3 and MEH-PPV are used as the light emitting layer (35), the performance of the light emitting device (30) is sensitive to oxygen and water molecules. Specifically, the light emitting performance of the light emitting device (30) will degrade when a current is applied to the light emitting layer (35). Hence, there is a need to adopt a second substrate (38) in order to prevent the exposure of the light emitting layer (35) to room atmosphere. To achieve this, the second substrate (38) is positioned on the light emitting layer (35) that supported by the first substrate (31) and sealed off under an inert atmosphere such as nitrogen (Ni) or argon (Ar) using an epoxy (39). The epoxy (40) is preferably ones without solvent and is curable upon exposure to an ultraviolet light. One example of such epoxy is: OP-4-20641 from DYMAX@.

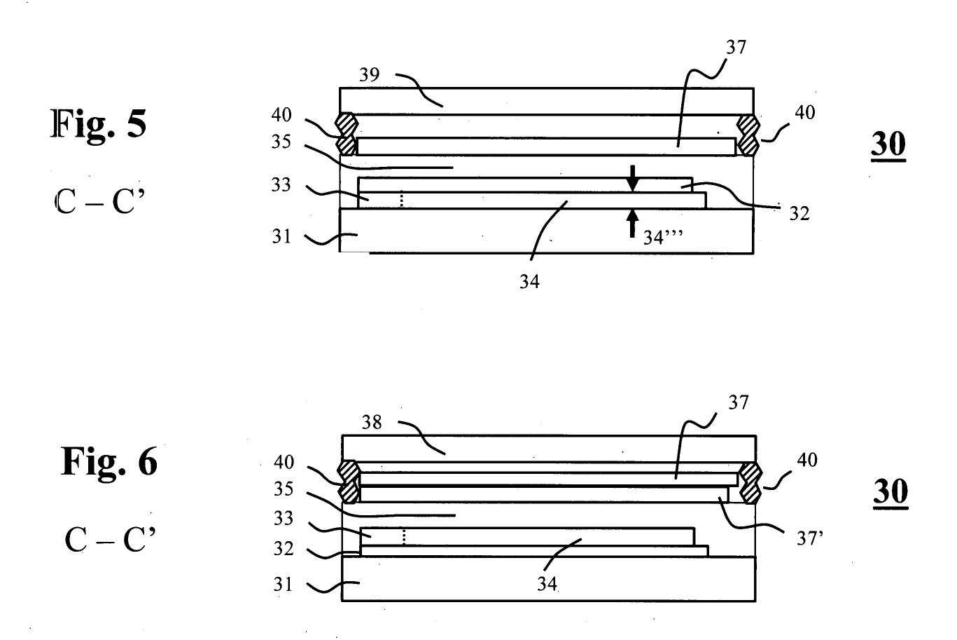

It should be pointed out that the above description such as the one shown in FIG. 4, the first grid electrode (34) is deposited on the first electrode (32) for the reduction of the series resistance of the first electrode (32). As shown in FIG. 5, the same reduction effect of the series resistance may well be achieved by having the first grid electrode (34) deposited on the first substrate (31) before depositing the first electrode (32). It should be noted that other numerals in FIG. 5 have same meaning as those in FIG. 4 and will not be repeated here.

The second electrode (37) the light emitting device (30) is a metal with low resistivity and could be selected from a group such as: Al, Au, Cu, Ti, Cr and their combinations. However, materials of the second electrode (37) could also be selected from a group of electrically conducting and optically transparent metal oxides such as ITO and ZnO. When metal oxides are selected as the second electrode (37), a second grid electrode (37′ in FIG. 6) will be required in order to reduce the series resistance of the second electrode (37). Materials for the second grid electrode (37′) could be selected from a group such as: Al, Au, Cu, Ti, Cr and their combinations. All other numerals in FIG. 6 have the same meaning as those in FIG. 3 and 4.

According to this invention, the series resistance of the first electrode (32) is reduced by incorporating the first grid electrode (34) whereas the series resistance of the second electrode (37) is reduced by incorporating the second grid electrode (37′). In this manner, when a current is applied to induce light emission in the light emitting layer (35), a portion of the current flowing through the column (data) line (33) to the light emitting layer (35) will be carried by the first grid electrode (34), whereas part of the current will flow through the second grid electrode (37′) in addition to the part flowing through the second electrode (37).

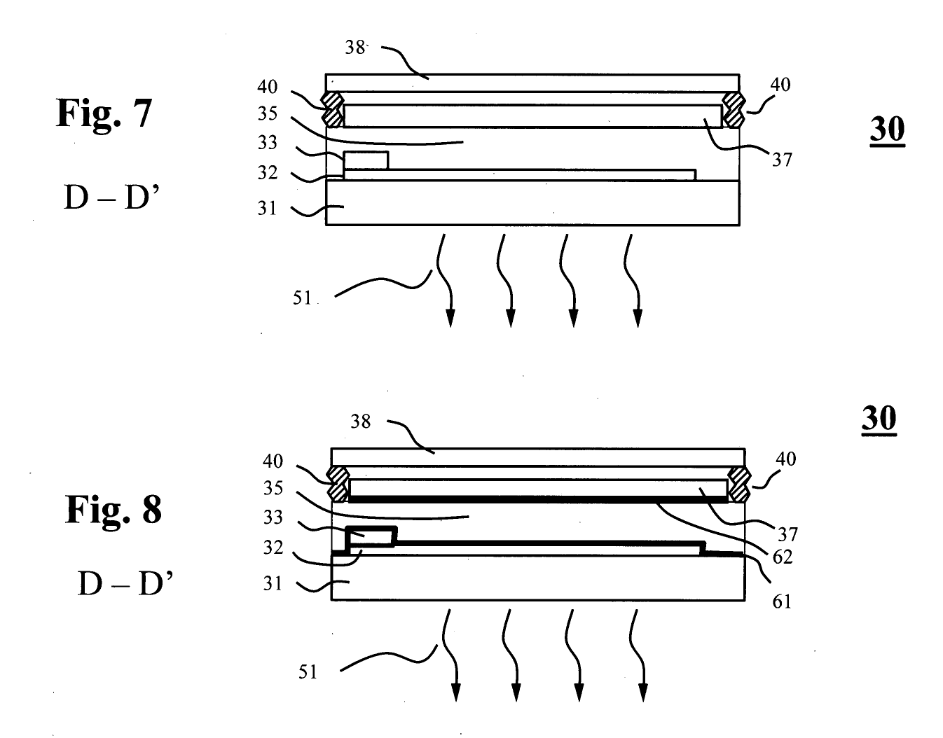

FIG. 7 gives a cross-sectional view of the light emitting device (30) along D-D′ in FIG. 3. When a current is allowed to flow through the light emitting layer (35), light (51) will be generated and will emit through the optically transparent first electrode (32). In this figure, the first grid electrode (34) and the second grid electrode (37′) are not visible.

It may be possible that the materials for the first electrode (32) and the materials for the second electrode (37) which make direct contact to the light emitting layer (35) are not compatible with the light emitting layer (35) to achieve a maximum light emitting efficiency. For instance, when ITO which has a large work function, is selected as the material for the first electrode (32), it is preferable to employ it as a hole-injection source. In order to further improve the hole-injection efficiency, it is favorable to deposit a hole-transport layer (61) as shown in FIG. 8, on the first electrode (32) before depositing the light emitting layer (35). The materials of the hole-transport layer (61) may be selected from a group such as: polyaniline, polythiothene, and polypyrole etc. One example of the hole-transport layer (61) is poly(3,4-ethylene-dioxythiophene) (PEDOT:PSS, Bayer Batron 4083). In such a device, the second electrode (37) is acting as the electron transport layer. To achieve a high injection efficiency of electrons, the work function of the materials of the second electrode (37) should be close or more preferably smaller than the electron affinity of the light emitting layer (35). In order to improve further the electron injection efficiency, it is preferable to deposit an electron-transport layer (62) on the light emitting layer (35) before depositing the second electrode (37). It is noted that all numbers for device (30) in FIG. 8 have the same meaning as those in FIG. 7 and will not be repeated here.

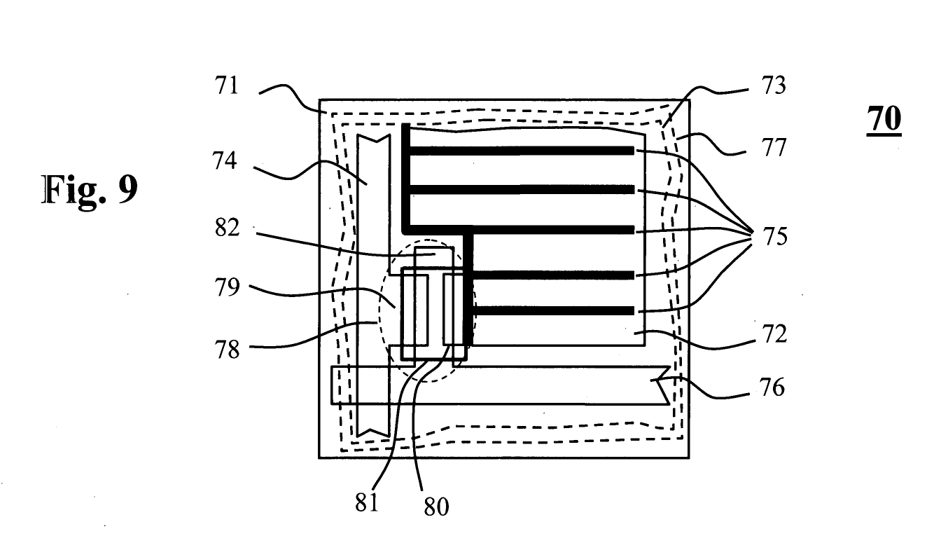

The present invention may well be employed in an active matrix light emitting array containing a plurality of light emitting devices (70) as shown in FIG. 9. The light emitting device (70) consists of a first substrate (71), a first electrode (72) for contacting to a light emitting layer (73), a column line (74) for supplying current to the first electrode (72), a first grid electrode (75), a row line (76), and a second electrode (77). The first electrode (72) is selected from a group of electrically conducting and optically transparent materials including: ITO and ZnO. In order to reduce the series resistance of the first electrode (72) having a resistivity about 10⁻³ ohm-cm, a first grid electrode (75) of metallic nature is disposed thereon. The materials of the first grid electrode (75) are selected from a group of materials with very low electrical resistivity (about 10⁻⁶ ohm-cm) such as: Al, Au, Cu, Ti, Cr and their combinations. Alternately, a multilayer structure may be selected for the first grid electrode (75) in order to improve the adhesion of the first grid electrode (75) to the first electrode (72). Electrical current from the column line (74) to the first electrode (72) is controlled by a thin film transistor (TFT, 78). The TFT (78) consists of a source (79), a drain (80), an active channel layer (81) and a gate (82). The gate (82) is connected electrically to the row line (76) for switching on/off the active channel layer (81) to allow for or to prevent from an electrical current from the source (79) to reach the drain (80). A plurality of first grid lines (75) is disposed on the first electrode (72) which is making direct electrical contact to the source (79) through a row line or gate line (82). Hence the series resistance associated with the first electrode (72) can be reduced.

What is claimed is:

1. A light emitting device with reduced electrode resistance for an electronic display array comprising:
a first substrate;
a first electrode;
a plurality of first grid electrodes to reduce effective series resistance of said first electrode, each of said first grid electrodes has a width, a thickness, a length and a spacing between adjacent grids of said first grid electrode;
a light emitting layer; and
a second electrode.

2. A light emitting device with reduced electrode resistance for an electronic display array as defined in claim 1, wherein said first substrate is optically transparent and is selected from a material group comprising: glass substrates, plastic sheets.

3. A light emitting device with reduced electrode resistance for an electronic display array as defined in claim 1, wherein said first electrode is selected from a material group comprising: indium tin oxide, zinc oxide and their combinations.

4. A light emitting device with reduced electrode resistance for an electronic display array as defined in claim 1, wherein said first grid electrode is selected from a material group comprising: Al, Au, Cu, Ti, Cr and their combinations.

5. A light emitting device with reduced electrode resistance for an electronic display array as defined in claim 1, wherein said first grid electrode is deposited on top of said first electrode and underneath said light emitting layer.

6. A light emitting device with reduced electrode resistance for an electronic display array as defined in claim 1, wherein said first grid electrode is deposited on top of said first substrate and underneath said first electrode.

7. A light emitting device with reduced electrode resistance for an electronic display array as defined in claim 1, wherein said light emitting layer is selected from a material group of small molecule organic semiconductors and large molecule organic semiconductors.

8. A light emitting device with reduced electrode resistance for an electronic display array as defined in claim 1, wherein said second electrode is selected from a material group comprising: Al, Au, Cu, Ti, Cr and their combinations.

9. A light emitting device with reduced electrode resistance for an electronic display array as defined in claim 1, wherein said second electrode is optically transparent and is selected from a material group comprising: indium tin oxide, zinc oxide and their combinations.

10. A light emitting device with reduced electrode resistance for an electronic display array as defined in claim 1; further comprise a second grid electrode deposited between said light emitting layer and said second electrode to reduce effective series resistance of said second electrode; each of said second grid electrodes has a width, a thickness, a length and a spacing between adjacent grids of said second grid electrode; wherein amount of reduction of said effective series resistance is controlled by selecting said width, said thickness and resistivity of said second grid electrodes.

11. A light emitting device with reduced electrode resistance for an electronic display array as defined in claim 1; further comprise a second grid electrode deposited on top of said second electrode to reduce effective series resistance of said second electrode, each of said second grid electrodes has a width, a thickness, a length and a spacing between adjacent grids of said second grid electrode; wherein amount of reduction of said effective series resistance is controlled by selecting said width, said thickness and resistivity of said second grid electrodes.

12. A light emitting device with reduced electrode resistance for an electronic display array as defined in claim 1; further comprising a hole-transport layer to increase injection of holes from said first electrode into said light emitting layer, said hole-transport layer being deposited and covers at least a portion of said first electrode.

13. A light emitting device with reduced electrode resistance for an electronic display array as defined in claim 1; further comprising an electron-transport layer to increase injection of electrons from said second electrode into said light emitting layer, said electron-transport layer being deposited and covers at least a portion of said light emitting layer.

14. A light emitting device with reduced electrode resistance for an electronic display array as defined in claim 1, wherein amount of reduction of said effective series resistance is controlled by selecting said width, thickness and resistivity of said first grid electrodes.

15. A light emitting device with reduced electrode resistance for an electronic display array as defined in claim 1; further comprise a second substrate to seal off said organic semiconductor in an inert atmosphere by an epoxy.
